(19) United States
(12) Patent Application Publication
(10) Pub. No.: US 2011/0033980 A1
(43) Pub. Date: Feb. 10, 2011

(54) STACK PACKAGE THAT PREVENTS WARPING AND CRACKING OF A WAFER AND SEMICONDUCTOR CHIP AND METHOD FOR MANUFACTURING THE SAME

(75) Inventor: Qwan Ho CHUNG, Gyeonggi-do (KR)

Correspondence Address: LADAS & PARRY LLP, 224 SOUTH MICHIGAN AVENUE, SUITE 1600, CHICAGO, IL, 60604, US

(73) Assignee: HYNIX SEMICONDUCTOR INC., Kyoungki-do (KR)

(21) Appl. No.: 12/908,340

(22) Filed: Oct. 20, 2010

Related U.S. Application Data
(62) Division of application No. 11/869,024, filed on Oct. 9, 2007.

(30) Foreign Application Priority Data
Jun. 26, 2007 (KR) 10-2007-0063181

(51) Int. Cl. H01L 21/50

(52) U.S. Cl. 438/109; 257/E21.499

(57) ABSTRACT

A stack package and a method for manufacturing the same. The stack package includes first and second semiconductor chips placed such that surfaces thereof, on which bonding pads are formed, face each other; a plurality of through-silicon vias formed in the first and second semiconductor chips; and a plurality of redistribution layers formed on the surfaces of the first and second semiconductor chips to connect the through-silicon vias to the corresponding bonding pad, wherein the redistribution layers of the first and second semiconductor chips contact each other. By forming the stack package in this manner, it is possible to prevent pick-up error and cracks from forming during the manufacturing process, and therefore the stack package can be reliable formed.

### CROSS-REFERENCE TO RELATED APPLICATIONS

The present application claims priority to Korean patent application number 10-2007-0063181 filed on Jun. 26, 2007, which is incorporated herein by reference in its entirety.

### BACKGROUND OF THE INVENTION

The present invention relates to a stack package and a method for manufacturing the same, and more particularly, to a stack package which prevents a wafer and semiconductor chips from being warped and also prevents cracks from occurring during is a manufacturing process, and a method for manufacturing the same.

The packaging technology for a semiconductor integrated circuit has been continuously evolving to meet the demands of miniaturization and high capacity. Recently, various techniques for stack packages have been disclosed in the art to provide satisfactory results in terms of miniaturization, high capacity, and mounting efficiency.

The term “stack”, as referred to in the semiconductor industry, means to vertically pile at least two chips or packages. In the case of a memory device, by stacking chips or packages it is possible to both realize a product having memory capacity greater than that obtainable through semiconductor integration processes and improve mounting area utilization efficiency.

Stack package manufacturing methods can be divided into a first method, in which individual semiconductor chips are stacked and the stacked semiconductor chips are packaged, and a second method, in which individually packaged semiconductor chips are stacked upon one another. In stack packages, electrical connections are formed by metal wires or through-silicon vias.

FIG. 1 is cross-sectional view illustrating a conventional stack package using metal wires.

Referring to FIG. 1, in a conventional stack package 100 using metal wires, at least two semiconductor chips 110 are stacked on a substrate 120 by the medium of adhesive 114, and the is respective chips 110 and the substrate 120 are electrically connected with each other by metal wires 116.

In FIG. 1, the unexplained reference numeral 112 designates bonding pads, 122 connection pads, 124 ball lands, 170 outside connection terminals, and 190 an encapsulant.

However, in the conventional stack package 100 using metal wires, since electrical signal exchange is conducted through metal wires 116, an operation speed of each semiconductor chip 110 is slow. Also, using the plurality of metal wires 116 causes the electrical characteristics of each chip 110 to be degraded. Further, in the conventional stack package 100 using metal wires, in order to form electrical connections using the metal wires 116 additional area in the substrate for accommodating the metal wires 116 is needed, and therefore the size of the stack package 100 increases. Additionally, in the conventional stack package 100 using metal wires, a gap is needed to bond the metal wires 116 to the respective chips 110, thus requiring an increase in the overall height of the stack package 100.

Therefore, in order to: overcome the problems of the stack package using metal wires, prevent the electrical characteristics of the stack package from being degraded, and enable miniaturization of the stack package; a stack package using through-silicon vias (TSVs) has been suggested in the art.

FIG. 2 is cross-sectional view illustrating a conventional stack package using through-silicon vias.

Referring to FIG. 2, in a conventional stack package 200 using through-silicon vias, semiconductor chips 210 having through-silicon vias 230 formed therein are stacked on a substrate 220 in a manner such that the through-silicon vias 230 of the chips 210 face each other.

In FIG. 2, the unexplained reference numeral 212 designates an insulation layer, 214 a metal seed layer, 222 connection pads, 224 ball lands, 270 outside connection terminals, and 218 metal lines.

In the stack package 200 using through-silicon vias, since electrical connections are formed by the through-silicon vias 230, it is possible to prevent the electrical characteristics of each chip 210 from being degraded. Therefore, the operation speed of the semiconductor chip 210 can be increased, and the semiconductor chip 210 can be miniaturized.

Nevertheless, in the case where the stack package is formed using through-silicon vias at wafer level or chip level, the wafers or semiconductor chips to be stacked have a significantly decreased thickness due to a grinding process for forming the through-silicon vias. Therefore, when stacking the wafers or semiconductor chips having the through-silicon vias, the wafers or the semiconductor chips are likely to be warped due to a difference in thermal expansion coefficient, and it is difficult to properly stack the wafers or the semiconductor chips. Specifically, a pick-up error can occur and cracks can be formed in the wafers or the semiconductor chips causing the manufacturing yield to decrease.

### SUMMARY OF THE INVENTION

The embodiments of the present invention are directed to a stack package that prevents a wafer and semiconductor chips from being warped and prevents cracks from occurring in a manufacturing process, and a method for manufacturing the same.

Additionally, the embodiments of the present invention are directed to a stack package that keeps manufacturing yield from decreasing by preventing a wafer and semiconductor chips from being warped and preventing cracks from occurring, and a method for manufacturing the same.

In one aspect, a stack package comprises first and second semiconductor chips placed such that surfaces thereof, on which bonding pads are formed, face each other; a plurality of through-silicon vias formed in the first and second semiconductor chips; and a plurality of redistribution layers formed on the surfaces of the first and second semiconductor chips to connect the through-silicon vias to the corresponding bonding pad, wherein the redistribution layers of the first semiconductor chip contact the corresponding redistribution layers of the second semiconductor chip.

The through-silicon vias and the redistribution layers may be integrally formed with each other.

The through-silicon vias and the redistribution layers can be formed of tin (Sn), nickel (Ni), copper (Cu), aurum (Au), aluminum (Al), or an alloy thereof.

The redistribution layers of the first semiconductor chip and the redistribution layers of the second semiconductor chip may be brought into contact with each other by the medium of anisotropic conductive film or solder paste.

The stack package further comprises a filler material filled in a space between the first and second semiconductor chips not occupied by the redistribution layers that contact each other.

The stack package further comprises a substrate to which the stacked first and second semiconductor chips are attached.

The stack package further comprises a capping layer formed on the semiconductor chip which is not attached to the substrate.

In another aspect, a stack package includes at least two stacked package units, each package unit comprising first and second semiconductor chips placed such that surfaces thereof, on which bonding pads are formed, face each other; a plurality of through-silicon vias formed in the first and second semiconductor chips; and a plurality of redistribution layers formed on the surfaces of the first and second semiconductor chips to connect the through-silicon vias to the corresponding bonding pad and such that the redistribution layers of the first semiconductor chips contact the corresponding redistribution layers of the second semiconductor chip, wherein the package units are stacked such that the through-silicon vias thereof are brought into contact with each other.

The through-silicon vias and the redistribution layers may be integrally formed with each other.

The through-silicon vias and the redistribution layers are formed of tin (Sn), nickel (Ni), copper (Cu), aurum (Au), aluminum (Al), or an alloy thereof.

The redistribution layers in each package unit and the through-silicon vias in the stacked package units can be brought into contact with each other by the medium of anisotropic conductive film or solder paste.

The stack package may further comprises filler materials filled in a space between the first and second semiconductor chips in each package unit that is not occupied by the re-rounding lines. The stack package may also comprise a filler material filled in the space between the stacked package units where the through-silicon vias do not contact each other.

The stack package further comprises a substrate to which the stacked package units are attached.

The stack package further comprises a capping layer formed on an upwardly positioned semiconductor chip of an uppermost package unit in the stacked package units.

In still another aspect, a method for manufacturing a stack package comprises the steps of defining a plurality of grooves in each of first and second wafers which comprises semiconductor chips each having a plurality of bonding pads, the grooves being formed to a depth such that the grooves do not pass through the first and second wafers; forming through-silicon vias in the grooves of the first and second wafers and redistribution layers for connecting the through-silicon vias to the corresponding bonding pads; attaching the first and second wafers to each other such that corresponding redistribution layers thereof are brought into contact with each other; grinding lower surfaces of the first and second wafers such that the through-silicon vias formed in the first and second wafers are exposed; and sawing the attached first and second wafers between the semiconductor chips thereby forming a plurality of package units.

The step of forming the through-silicon vias and the redistribution layers comprises the steps of forming an insulation layer on sidewalls of the grooves defined in the first and second wafers; forming a metal seed layer on each wafer, the insulation layers, and the bottom of each groove; forming a metal layer on the metal seed layer to fill the grooves; and patterning the metal layer and the metal seed layer.

The through-silicon vias and the redistribution layers may be formed of tin (Sn), nickel (Ni), copper (Cu), aurum (Au), is aluminum (Al), or an alloy thereof.

A medium of anosotripic conductive film or solder paste may be formed between the corresponding redistribution layers of the first and second wafer to effectuate contact.

Between the step of attaching the first and second wafers to each other and the step of grinding the lower surfaces of the first and second wafers, the method may further comprise the step of filling a filler material in a space between the attached first and second wafers that is not occupied by the redistribution layers.

The step of grinding the lower surfaces of the first and second wafers comprises the steps of attaching a first tape to the lower surface of the first wafer; grinding the lower surface of the second wafer such that the through-silicon via is exposed; removing the first tape attached to the lower surface of the first wafer; attaching a second tape to the lower surface of the grinded second wafer; grinding the lower surface of the first wafer such that the through-silicon via is exposed; and removing the second tape attached to the lower surface of the second wafer.

After the step of forming the plurality of package units, the method further comprises the steps of attaching the formed package unit to a substrate; and forming a capping layer on an upwardly positioned semiconductor chip of the package unit.

After the step of forming the plurality of package units, the method further comprises the steps of stacking at least two package units such that the through-silicon vias thereof are brought into contact with each other; attaching the stacked package units to a substrate; and forming a capping layer on an upwardly positioned semiconductor chip of an uppermost package unit in the stacked package units.

A medium of anisotropic conductive film or solder paste may be formed between the through-silicon vias to effectuate the contact.

### BRIEF DESCRIPTION OF THE DRAWINGS

FIG. 1 is cross-sectional view illustrating a conventional stack package using metal wires.

FIG. 2 is cross-sectional view illustrating a conventional stack package using through-silicon vias.

FIG. 3 is a cross-sectional view illustrating a stack package in accordance with an embodiment of the present invention.

FIGS. 4A through 4I are cross-sectional views illustrating the processes of a method for manufacturing a stack package in accordance with another embodiment of the present invention.

FIG. 5 is a cross-sectional view illustrating a stack package in accordance with still another embodiment of the present invention.

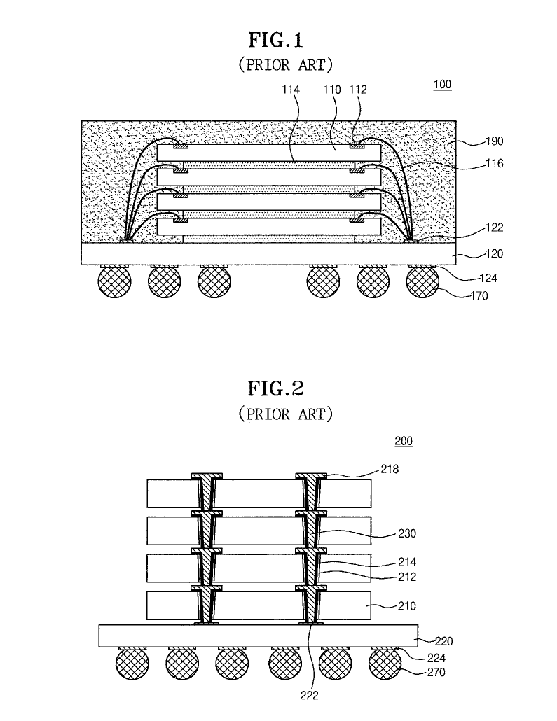

### DESCRIPTION OF SPECIFIC EMBODIMENTS

In the present invention, a method in which the lower surfaces of two wafers are back-grinded after stacking the wafers to be electrically connected is used, whereby a stack package using through-silicon vias is realized at a wafer level or a chip level. Also, in the present invention, the stack package is realized in a manner such that a single package unit or a plurality of package units is mounted to an external circuit having a substrate by the through-silicon vias. The through-silicon vias are exposed by back-grinding the lower surfaces of the respective stacked wafers. By doing this, the present invention solves the problems, which are caused by the decrease in thickness of the wafer and semiconductor chip, in the conventional art.

That is to say, in the present invention, first and second semiconductor chips, which are formed with through-silicon vias and redistribution layers that connect the through-silicon vias and bonding pads to each other, are attached to each other at a wafer level in a manner such that the redistribution layers are brought into contact with each other. Then, by mounting the resultant package to the substrate, a stack package is formed. Additionally, a plurality of package units can be stacked and then mounted to the substrate, thereby forming a stack package.

Accordingly, in the present invention, since the stack package is formed by back-grinded the lower surfaces of the two wafers (after stacking the wafers that are to be electrically connected) in a manner such that the through-silicon vias are exposed through the lower surfaces of the wafers. By forming the package in this manner, it is possible to suppress or prevent a pick-up error and cracks which occur due to warpage resulting from the decreased thickness of a wafer. Therefore, the present invention can solve the problems caused in a conventional method for manufacturing a stack package.

As a consequence, in the present invention a stack package can be reliably formed, thereby increasing the manufacturing yield of a stack package, and specifically, a stack package having a decreased thickness can be easily realized.

Hereafter, a stack package and a method for manufacturing the same will be described in detail.

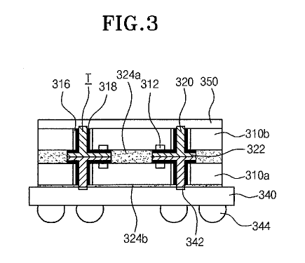

FIG. 3 is a cross-sectional view illustrating a stack package in accordance with an embodiment of the present invention.

Referring to FIG. 3, first and second semiconductor chips 310a and 310b are placed such that the surfaces thereof (on which bonding pads 312 are formed) face each other. Through-silicon vias 320 are formed in the respective first and second semiconductor chips 310a and 310b, and redistribution layers 322 are formed between the through-silicon vias 320 and the bonding pads 312. The first and second semiconductor chips 310a and 310b are electrically and physically connected to each other by a medium of solder paste (not shown) formed between the redistribution layers 322, and a first filler material 324a such as non-conductive paste filled in the space between the first and second semiconductor chips 310a and 310b.

The stacked first and second semiconductor chips 310a and 310b are attached to a substrate 340 which has connection pads 342 on the upper surface thereof. Solder balls 344 are attached to the lower surface of the substrate 340. The downwardly positioned first semiconductor chip 310a and the substrate 340 are electrically and physically connected to each other by a medium of solder paste (not shown) formed between the through-silicon vias 320 of the first semiconductor chip 310a and the connection pads 342 of the substrate 340, and a second filler material 324b such as non-conductive paste filled in the space between the first semiconductor chip 310a and the substrate 340.

The stack of the first and second semiconductor chips 310a and 310b and the attachment between the first semiconductor chip 310a and the substrate 340 may also be carried out using anisotropic conductive film.

The through-silicon vias 320 and the redistribution layers 322 are formed of tin (Sn), nickel (Ni), copper (Cu), aurum (Au), aluminum (Al), or an alloy thereof, and are integrated with each other. The unexplained reference numeral 316 designates an insulation layer, and 318 designates a metal seed layer.

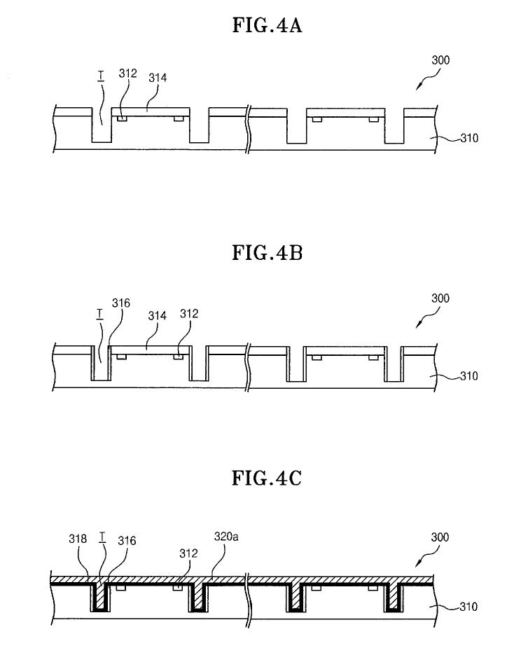

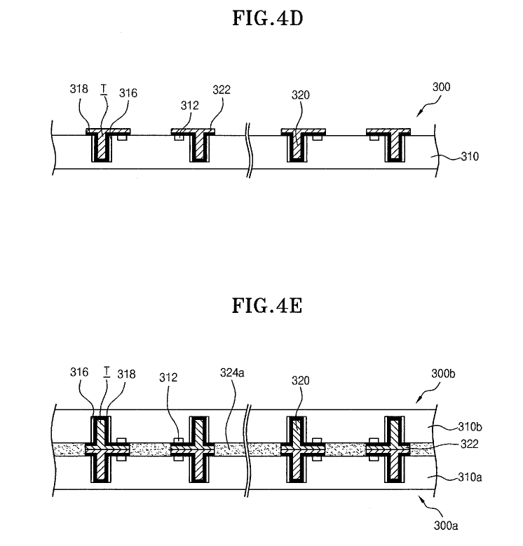

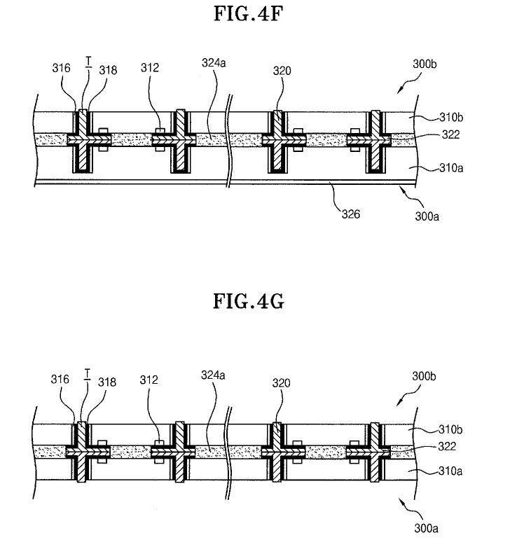

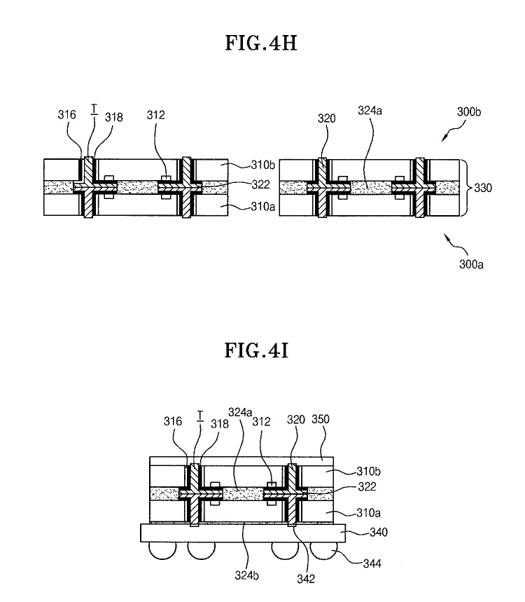

FIGS. 4A through 4I are cross-sectional views illustrating the process steps of a method for manufacturing a stack package in accordance with another embodiment of the present invention.

Referring to FIG. 4A, a mask pattern 314 is formed on a wafer 300 that has undergone a manufacturing process such that the wafer comprises a plurality of semiconductor chips 310 each having a plurality of bonding pads 312 on the upper surface thereof and a plurality of grooves T defined to an appropriate depth such that the groove does not pass through the wafer 300.

Referring to FIG. 4B, an insulation layer 316 is formed on the upper surface of the wafer 300 and the surfaces of the grooves T. An etch-back process is then conducted such that the insulation layer 316 remains only on the sidewalls of the grooves T.

Referring to FIG. 4C, a metal seed layer 318 is formed on the wafer 300, the insulation layer 316 formed on the sidewalls of the grooves T, and the bottom of the groove. Then, by conducting a plating process on the metal seed layer 318, a metal layer 320a is formed on the wafer to fill the grooves T. The metal layer 320a is formed of tin (Sn), nickel (Ni), copper (Cu), aurum (Au), aluminum (Al), or an alloy thereof.

Referring to FIG. 4D, an etch-back process is conducted on the metal layer 320a so that the height of the metal layer 320a is decreased to a thickness appropriate for forming the desired stack package. Thereafter, by partially removing the metal layer 320a and the metal seed layer 318 through a patterning process, redistribution layers 322 are formed to connect the bonding pads 312 and through-silicon vias 320 to each other.

Referring to FIG. 4E, after forming a second wafer 300b having the same structure as that shown in FIG. 4D, first and second wafers 300a and 300b are attached to each other such that the corresponding redistribution layers 322 are brought into contact with each other. The first and second wafers 300a and 300b are electrically and physically connected to each other by the medium of solder paste (not shown) interposed between the redistribution layers 322 (which contact each other), and a first filler material 324a filled in the space between the first and second wafers 300a and 300b excluding the redistribution layers 322. Alternatively, the first and second wafers 300a and 300b can be electrically and physically connected to each other by the medium of an anisotropic conductive film formed both in the space between the first and second wafers 300a and 300b and between the redistribution layers 322.

Referring to FIG. 4F, a grinding laminate tape 326 is attached to the lower surfaces of the first wafer 300a. By conducting at least one of a grinding process and an etching process, the lower surface of the second wafer 300b is back-grinded, thereby exposing the through-silicon vias 320 of the second wafer 300b.

Referring to FIG. 4G, the grinding laminate tape 326 is removed from the lower surface of the first wafer 300a. The through-silicon vias 320 of the first wafer 300a are then exposed by the same process of FIG. 4F.

Referring to FIG. 4H, a tape (not shown) is attached to the lower surface of the first wafer 300a or the second wafer 300b in order to conduct a sawing process. The first and second wafers 300a and 300b attached to each other are then sawed, and the combination of the first and second wafers 300a and 300b is divided into a chip level. At this time, the semiconductor chips 310a and 310b stacked at the chip level are classified as a package unit 330. By stacking a plurality of package units 330, a stack package can be formed.

Referring to FIG. 4I, the first and second semiconductor chips 310a and 310b stacked in the chip level are attached to a substrate 340 that has connection pads 342 on the upper surface thereof. Solder balls 344 are attached to the lower surface of the substrate 340. A capping layer 350 is formed on the lower surface of the upwardly positioned second semiconductor chip 310b in order to protect the second semiconductor chip 310b. The downwardly positioned first semiconductor chip 310a and the substrate 340 are electrically and physically connected to each other by the medium of solder paste (not shown) interposed between the through-silicon vias 320 of the downwardly positioned first semiconductor chip 310a and the connection pads 342 of the substrate 340, and also through a second filler material 324b filled in the space between the first semiconductor chip 310a and the substrate 340. Alternatively, the first semiconductor chip 310a and the substrate 340 can be electrically and physically connected to each other by the medium of anisotropic conductive film formed both in the space between the first semiconductor chip 310a and the substrate 340 and between the through-silicon vias 320 and the connection pads 342 of the substrate 340.

As described above, in the present embodiment, by back-grinding the lower surfaces of the respective wafer after two wafers to be electrically connected with each other are stacked, a stack package is formed with through-silicon vias that are exposed through the lower surfaces of the respective wafers. It is therefore possible to solve the problems that happen during the process of forming a stack package which are caused due to the warpage resulting from the use of a wafer having decreased thickness. Accordingly, in the present invention a stack package can be reliably formed, thereby increasing the manufacturing yield of the stack package, and a stack package having a decreased thickness can be easily realized.

Meanwhile, in the present invention, a stack package can be formed by stacking a plurality of package units (formed in FIG. 4H) upon one another.

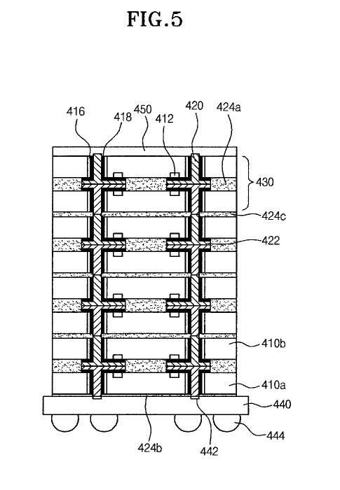

FIG. 5 is a cross-sectional view illustrating a stack package in accordance with still another embodiment of the present invention.

Referring to FIG. 5, at least two package units 430, which have the same structure as shown in FIG. 4H, are stacked such that the through-silicon vias 420 of the respective package units 430 are brought into contact with each other. The stacked package units 430 are attached to a substrate 440 that has a plurality of connection pads 442 on the upper surface thereof. A capping layer 450 is formed on the uppermost stacked package unit 430, and solder balls 444 are formed on the lower surface of the substrate 440.

The package units 430 are electrically and physically connected to each other by a medium of solder paste (not shown) interposed between the through-silicon vias 420 of the respective package units 430, and a third filler material 424c (such as non-conductive paste) filled in the space between the package units 430 excluding the through-silicon vias 420. Alternatively, the package units 430 can be electrically and physically connected to each other by the medium of isotropic conductive film formed both in the space between the package units 430 and between the through-silicon vias 420.

The method for preparing the package units 430 to form the stack package is the same as that shown in FIGS. 4A through 4F, and the process for subsequently attaching the package units 430 to the substrate 440 is the same as that shown in FIG. 4I.

As is apparent from the above description, in the present invention, a stack package is formed in a manner where the lower surfaces of the wafers are back-grinded after stacking two wafers to be electrically connected with each other. Therefore, it is possible to prevent a pick-up error and cracks from occurring during the process of forming the stack package due to warpage resulting from using wafers or semiconductor chips with a decreased thickness. Accordingly, in the present invention a stack package can be reliably formed, thereby increasing the manufacturing yield of the stack package, and a stack package having a decreased thickness can be easily realized.

Further, in the present invention, since a wafer sawing process is conducted after stacking two wafers, a laser sawing process for preventing the occurrence of cracks is not necessarily required, and therefore, the sawing process can be conducted using the conventional equipment.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for manufacturing a stack package, comprising the steps of:
defining a plurality of grooves in an upper surface of a first wafer and a second wafer such that the grooves do not pass through the entire depth of the first and second wafers, wherein the first and second wafers each have a plurality of semiconductor chips and each semiconductor chip has a plurality of bonding pads;
forming through-silicon vias in the grooves of the first and second wafers;
forming redistribution layers on the upper surface of the first and second wafers for connecting each through-silicon vias to its corresponding bonding pad;
attaching the upper surface of the first wafer to the upper surface of the second wafers, such that the corresponding redistribution layers are brought into contact with each other;
grinding a lower surface of the first and second wafer such that the through-silicon vias formed in the first and second wafers are exposed; and
sawing the attached first and second wafers between the semiconductor chips in the first and second wafers, such that a plurality of package units is formed.

2. The method according to claim 1, wherein the step of forming the through-silicon vias and the redistribution layers comprises the steps of:
forming an insulation layer on sidewalls of the grooves defined in the first and second wafers;
forming a metal seed layer on the upper surface of each wafer, the insulation layer on the sidewalls of the grooves, and the bottom of each groove;
forming a metal layer on the metal seed layer to fill the grooves; and
pattering the metal layer and the metal seed layer.

3. The method according to claim 2, wherein the through-silicon vias and the redistribution layers are formed of tin (Sn), nickel (Ni), copper (Cu), aurum (Au), aluminum (Al), or an alloy thereof.

4. The method according to claim 2, wherein a medium of anisotropic conductive film or solder paste is formed between the redistribution layers of the first wafer and the redistribution layers of the second wafer

5. The method according to claim 1, further comprising:
between the step of attaching the first and second wafers to each other and the step of grinding the lower surfaces of the first and second wafers, filling a filler material in a space between the attached first and second wafers that is not occupied by the redistribution layers.

6. The method according to claim 1, wherein the step of grinding the lower surfaces of the first and second wafers comprises the steps of:
attaching a first tape to the lower surface of the first wafer;
grinding the lower surface of the second wafer such that the through-silicon via is exposed;
removing the first tape attached to the lower surface of the first wafer;
attaching a second tape to the lower surface of the grinded second wafer;
grinding the lower surface of the first wafer such that the through-silicon via is exposed; and
removing the second tape attached to the lower surface of the second wafer.

7. The method according to claim 1, further comprising the steps of:
after the step of forming the plurality of package units,
attaching the formed package unit to a substrate; and
forming a capping layer on an upwardly positioned semiconductor chip of the package unit.

8. The method according to claim 1, further comprising the steps of:
after the step of forming the plurality of package units
stacking a plurality of package units such that the exposed through-silicon vias thereof are brought into contact with each other;
attaching a bottommost stacked package unit to a substrate; and
forming a capping layer on a top side of the uppermost package unit in the stacked package.

9. The method according to claim 8, wherein a medium of an anisotropic conductive film or solder paste is formed between the through-silicon vias.
